(19) United States
(12) Patent Application Publication
(10) Pub. No.: US 2026/0087210 A1
(43) Pub. Date: Mar. 26, 2026

(54) METHOD FOR PREDICTING A CO2 STORAGE RISK ASSESSMENT

(71) Applicant: SHELL USA, INC., HOUSTON, TX (US)

(72) Inventors: Ligang LU, Houston, TX (US); Jie CHEN, Houston, TX (US); Ilyana FOLMAR, Houston, TX (US); Zexuan DONG, Houston, TX (US); Qiushuo SU, Houston, TX (US); Luiz Fernando GUEDES DOS SANTOS, Houston, TX (US)

(21) Appl. No.: 18/908,025

(22) Filed: Oct. 7, 2024

Related U.S. Application Data
(60) Provisional application No. 63/698,159, filed on Sep. 24, 2024.

(51) Int. Cl. G06F 30/28; G06F 30/27

(52) U.S. Cl. CPC G06F 30/28; G06F 30/27

(57) ABSTRACT

A method for predicting a CO₂ storage risk assessment includes uploading a well information file for a well located in a subsurface formation to the generative model. The well information file is queried to extract information relevant to a set of well integrity rules. The query and the extracted information are converted into numerical vectors in an embedding step. A semantic similarity search is conducted to find and rank text using the numerical vectors. An answer to query is generated by the generative model and provided to a classification process based on the set of well integrity rules. A prediction for a subsurface CO₂ storage risk assessment is computed for the well from the answer.

### FIELD OF THE INVENTION

The present invention relates to a method for predicting a CO₂ storage risk assessment, and, in particular, to a classification process for making the prediction.

### BACKGROUND OF THE INVENTION

The increased demand for energy resulting from worldwide economic growth and development has contributed to an increase in concentration of greenhouse gases (GHG) in the atmosphere. This has been regarded as one of the most important challenges facing humankind in the 21st century. To mitigate the effects of GHG, efforts have been made to reduce the global carbon footprint.

Efforts to mitigate the release of GHG have led to a variety of technologies such as CCUS or CCS (Carbon Capture, Utilization and Sequestration, or Carbon Capture and Storage). With respect to geologic sequestration, efforts have been directed towards injecting gaseous or supercritical CO₂ into a subsurface formation.

The use of depleted hydrocarbon reservoirs has been considered for CO₂ storage. Depleted oil and gas reservoirs are suitable locations for sequestering CO₂ owing to their rock and structural properties and access to required infrastructure. In particular, abandoned wells in these reservoirs can be used for injecting CO₂ without investing in drilling new wells saving both time and cost.

Li et al. (“Prediction of CO2 leakage risk for wells in carbon sequestration fields with an optimal artificial neural network” Intl J Greenhouse Gas Control 68:276-286; 2017)

CCS is currently constrained by the availability of sufficient de-risked pore space for safe storage. Depending on the type of geological storage in saline aquifers or depleted hydrocarbon bearing formations, multiple pathways could exist for CO₂ migration. It is important to understand the integrity of a well for assessing risk associated with CO₂ containment. In particular, it is important to determine the likelihood of undesirable leakage of CO₂ into unwanted areas, such as groundwater zones.

It is important to understand the integrity of a well for assessing risk associated with CO₂ containment. In particular, it is important to determine the likelihood of undesirable leakage of CO₂ into unwanted areas, such as groundwater zones.

Accordingly, significant effort is required from a subject matter expert to identify relevant information which often results in longer lead times of up to a year for a CO₂ sequestration site to mature. Reducing the lead time in maturing a site for CO₂ injection could result in faster CCS project delivery timelines and contribute to our broader goal of achieving net-zero targets.

One challenge in the well integrity evaluation is identification of potential CO₂ migration paths of fluids out of the storage complex. Depending on the areal location and the depth of penetration, legacy wells may be exposed to CO₂ plume and/or elevated bottomhole pressure due to the lifted formation brine (if CO₂ stored in a saline aquifer) propagating from CO₂ injection wells. Another challenge for injecting CO₂ into the depleted reservoir is related to CO₂ phase behaviour. Expansion of the CO₂ may lead to very low temperatures in the well, posing limitations on well design, integrity, and operability, and injectivity as hydrates may form. Alternatively, in case of a strong aquifer, water backfills the porous formation after the hydrocarbons are produced from the reservoir. Accordingly, a significant pressure is required for injecting CO₂ to overcome the water pressure in the formation and limited capacity is available for storage without potential risking caprock integrity. Compression of the gas requires energy with a related GHG footprint.

Another challenge facing the injection of CO₂ the structure of the subsurface formation. CO₂ is light i.e., less dense than water, and will naturally travel upwardly in the formation because of buoyancy. Therefore, the formation should have a high-quality seal to avoid leak paths that could result in release into the environment. When upward mobility is limited, CO₂ will then migrate laterally potentially encountering additional leaks paths related to lack of closure, faults, or improperly abandoned wells. This presents limitations of where CO₂ can be responsibly injected and necessitates extensive CO₂ monitoring activities for a prolonged period to ensure the CO₂ remains in the subsurface formation.

Lu et al. previously disclosed significant improvements in accuracy and efficiency of CO2 storage risk assessments in WO2024/059685A1 and WO2024/059689A1 (21 Mar. 2024). WO'685 provides a method for predicting a CO2 storage risk assessment by extracting data for a well located in a subterranean formation. The extracted data is selected to be relevant to a set of well integrity rules and is subjected to a classification process to compute a CO₂ storage risk assessment for the well. In WO'689, a method for inferring well integrity criterion for a CO₂ storage site risk assessment involves dependency-training a backpropagation-enable process to identify contextual relationships between elements of a training well data set and label-training the dependency-trained backpropagation-enabled process to assess a well integrity criterion.

The source documents used for the methods of WO'685 and WO'689 includes, for example, daily drilling reports, cementing reports, well completion reports, workover reports, abandonment reports, general well data, pressure tests, mud record, information about cores taken, geological reports, abandonment or plug back, casing or liner data, cement data, and/or daily work summary. These source documents are produced for and by people having a high skill level in the art of well drilling, completion, monitoring, and/or abandonment and, therefore, often provide limited contextual information. While the methods of WO'685 and WO'689 have greatly improved the efficiency of the risk assessment, it would be desirable to further improve the accuracy of the assessment produced from diverse data sources.

There remains a need to further improve accuracy and efficiency of CO₂ storage risk assessments.

### SUMMARY OF THE INVENTION

According to one aspect of the present invention, there is provided a method for predicting a CO₂ storage risk assessment, comprising the steps of: (a) providing a generative model; (b) determining a set of well integrity rules; (c) uploading a well information file for a well located in a subsurface formation to the generative model; (d) querying the well information file to extract information relevant to the set of well integrity rules from the well information file; (e) embedding to convert the query and the extracted information into numerical vectors; (f) conducting a semantic similarity search to find and rank text using the numerical vectors; (g) providing an answer to the query generated by the generative model to a classification process based on the set of well integrity rules; and (h) computing a prediction for a subsurface CO₂ storage risk assessment for the well from the answer generated in step (g).

### BRIEF DESCRIPTION OF THE DRAWINGS

The method of the present invention will be better understood by referring to the following detailed description of preferred embodiments and the drawings referenced therein, in which:

FIG. 1 is a block diagram illustrating the steps of one embodiment of the present invention;

FIG. 2 is a block diagram illustrating the steps of another embodiment of the present invention;

FIG. 3 is a block diagram illustrating the steps of a further embodiment of the present invention;

FIG. 4 is a schematic diagram of one example of a set of well integrity rules according to one embodiment of the present invention;

FIGS. 5 and 6 are examples of a risk assessment performed in accordance with one embodiment of the present invention for a single well and for three wells in the same formation;

FIG. 7 illustrates the results of Example 1;

FIGS. 8A and 8B illustrate the results of Example 2;

FIG. 9 illustrates the results of Example 3;

FIG. 10 A and 10B illustrate the results of Example 4;

FIGS. 11A and 11B illustrate the results of Example 5; and

FIGS. 12A and 12B illustrate the results of Example 6.

### DETAILED DESCRIPTION OF THE INVENTION

The present invention provides a method for predicting a CO₂ storage risk assessment from well information files. A well information file for a well located in a subsurface formation is uploaded to a generative model. Reference herein to a well information file will be understood to mean one or more well information files. The well information file is queried to extract information relevant to a set of well integrity rules. The query and the extracted information are converted into numerical vectors by an embedding step. A semantic similarity search is conducted to find and rank text using the numerical vectors. An answer to the query is generated by the generative model. The answer is provided to a classification process based on the set of well integrity rules. A prediction for a subsurface CO₂ storage risk assessment for the well is computed from the answer generated in the previous step. In one embodiment, preferably, the data is queried using an example learning technique selected from few-shot learning and one-shot learning. In another embodiment, the sematic similarity search further comprises using a domain knowledge base trained by an example learning technique selected from few-shot learning and one-shot learning

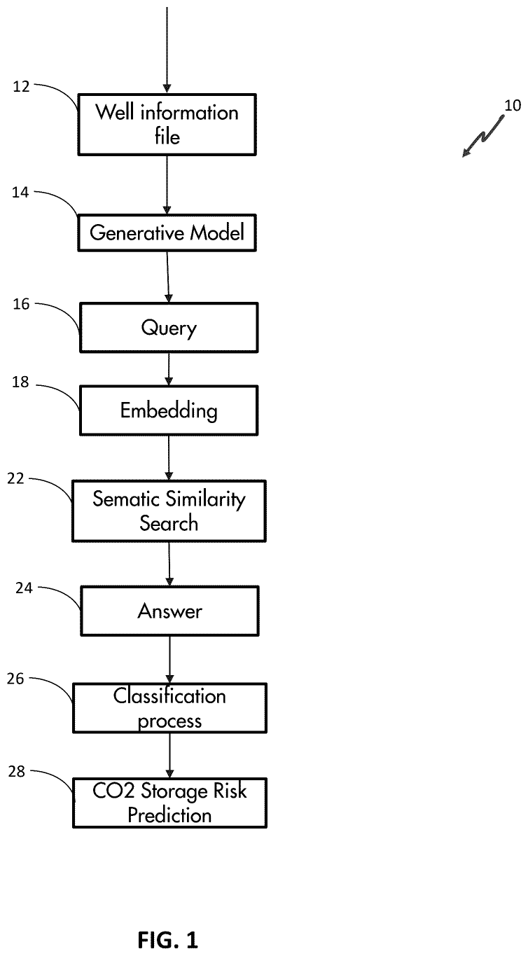

FIG. 1 is a block diagram illustrating an embodiment of the method of the present invention 10. A well information file 12 is provided. Analysis of well data is important for improving efficiency and accuracy of risk assessment for CCS sites. Well integrity evaluation involves doing a risk assessment by understanding a criterion, such as, without limitation, rock-to-rock isolation, cement bonding, casing, isolation of permeable zones, and isolation of groundwater zones. Verification is done through the evidence of present cement plugs and thickness, cemented casings, squeezed perforations in the wells, and combinations thereof.

However, when considering the use of an abandoned well, the well information file 12 may be decades old. Also, because the well information file 12 was generated for a different purpose, the well data is typically not set up in a standardized form for answering a well integrity query for purposes of CCS. For example, the well information file 12 may include, such as, for example, without limitation, daily drilling reports, cementing reports, well completion reports, workover reports, abandonment reports, general well data, pressure tests, mud record, information about cores taken, geological reports, abandonment or plug back, casing or liner data, cement data, and/or daily work summary. Other well information may include the depth of groundwater zone. The information for the well may be legacy information, recent information, and combinations thereof. Information relevant to well integrity rules include, for example, without limitation, stratigraphy, lithology, permeability, cap rock seal integrity, casing integrity, plug integrity, and depths. The well information file 12 may be of different types including, for example, without limitation, a portable document file (e.g., pdf), a presentation file (e.g., POWERPOINT®), a spreadsheet file (e.g., EXCEL™), a word processor file (e.g., WORD™), a text file, an image file, and combinations thereof.

As noted above, depleted oil and gas reservoirs have been considered for storing CO₂ because they have desirable structural features, in particular, seal and trap structures to hold CO₂ for long periods of time. Further, the sites often have infrastructure such as pipelines, and accessibility to roadways that can be reused for CCS sites. Abandoned wells drilled in these reservoirs can be used to inject CO₂ but because the wells may have been drilled from years to decades ago, a well integrity evaluation is important before making any injection plans.

Alternatively, or in addition, recent well information may be determined from existing or new wells.

Well information provided in well information files 12 is often voluminous and often available in non-searchable pdf and/or image files. For example, the information may be present in hundreds of pages for one well, often including handwritten notes, combined with typeset. For example, a report may have been completed by handwriting on a typeset form. Alternatively, or in addition, reports may be in tabular form with numerical values in a column having a heading several rows above the value. Often, unstandardized jargon, acronyms, and abbreviations were used in generating the original well information file 12. As examples, a perforation may be referred to as perf, perforate, perf'd, and the like, while cement may be referred to as cmt., cement and so on. Finally, units of measure and date formats are often used interchangeably.

The well information file 12 is uploaded to a generative model 14. Preferably, the generative model 14 is selected from a large-language model, a large vision model, and a large vision-language model. More preferably, the generative model 14 is a large-language model. In another embodiment, the generative model 14 is a retrainable model.

Examples of large-language models include, for example, without limitation, GPT-4™ (OpenAI), GPT-3™ (OpenAI), GPT-2™ (Open AI), ChatGPT™ (OpenAI), T5™ (Text-to-Text Transfer Transformer) by Google, XLNet™ (Carnegie Mellon University and Google), and RoBERTa™ (Robustly optimized BERT approach) by Facebook AI. A non-limiting example of a large vision model is GPT-4V™ (OpenAI).

The generative model 14 is pre-trained on a vast amount of text data and/or image data, implicitly learning a wide range of language patterns and tasks. A challenge with generative models 14 is that they are not typically trained with enough domain knowledge for a specific task, such as CO₂ storage risk assessment.

In addition, the generative model 14 may not have the privacy needed for interrogating confidential well information files 12. Accordingly, the well information file 12 may be uploaded directed to a generative model 14 or through a platform or interface that integrates with the generative model 14. For example, the generative model 14 may be accessed through an Application Programming Interface (API) to integrate the capabilities into an entity's own applications. The uploading step may include checking the file type and/or the content type for the well information file 12. Images in the well information file 12 may be extracted.

Further, there is a need for accuracy in the CO₂ storage risk assessment. This is contrary to the “creativity” of a generative model where unknown concepts result in so-called hallucinations, where the model creates an incorrect or inaccurate assessment. Accordingly, the generative model 14 is trained in the method of the present invention to extract data relevant to a set of well integrity rules from the well information file 12 when the user submits a query 16.

The set of well integrity rules is used for determining a classification process 26. Preferably, the set of well integrity rules is based on domain or industry guidance, and/or regulatory requirements.

The set of well integrity rules include technical criteria that can be used to determine the current well status and potential leak paths for CO₂ migration and/or pressure impact from the target formation. Examples of criteria that may be used in the set of well integrity criteria include, without limitation, presence of a cap rock seal, casing integrity, open or closed perforations in the wells, proximity to groundwater zone, isolation of groundwater zones using plugs or otherwise, fluid communication with a permeable zone, industry standards, industry guidelines, governmental regulations, and combinations thereof. Other suitable criteria will be understood by those skilled in the art.

In one embodiment of the present invention 10, in order to extract relevant well integrity information, the query 16 is submitted by an example learning technique selected from few-shot learning and one-shot learning. Few-shot learning and one-shot learning are machine learning techniques that enable models to make accurate predictions or recognize patterns based on a very small number of training examples. This is particularly useful for predicting a CO₂ storage risk assessment, where acquiring large, labeled datasets is challenging or expensive.

In another embodiment of the present invention 10, a domain knowledge base is provided. The domain knowledge base includes domain-specific documents, and examples of few-shot learning and one-shot learning based on domain expertise, and/or user feedback as one-shot examples.

In few-shot learning or one-shot learning, two sets of data are used, namely, the well information file 12 and the query itself. The query 16 is selected to contains examples that the model needs to classify based on the well information file 12. These examples help the model understand the specific task and generate accurate predictions based on minimal data. The term “few-shot” refers to training a model to interpret a few sources of input data that the model has not necessarily observed before. “Few” does not necessarily refer to “three” as may be interpreted in other contexts, but instead refers to a relatively small number when compared to other models known in the art. Few-shot learning refers to the training of machine learning algorithms using a very small set of training data (e.g., a handful of examples or images), as opposed to the very large set that is more often used. This commonly applies to the field of computer vision, where it is desirable to have an object categorization model work well without thousands of training examples.

The training of the model is premised in teaching the model what to do with unknown input examples rather than compare a given input example to each previously observed input to determine a closest match. Rather than evaluate individual inputs, the model is trained to evaluate relationships that exist between the various examples within the few-shot or one-shot.

In the query step 16, information relevant to the set of well integrity rules is extracted from the well information file 12.

In an embedding step 18, the extracted information and the query are converted into numerical vectors. Accordingly, words are represented in a continuous vector space to capture semantic relationships and contextual information. An embedding module may use a algorithm selected from, for example, without limitation, Word2Vec™ (Google), BERT™ (Bidirectional Encoder Representations from Transformers) by Google, or other suitable algorithms to generate the embeddings.

Thereafter, the numerical vectors are used in a semantic similarity search 22 to find and rank text or documents based on their semantic similarity to a given query. The semantic similarity search 22 provides more contextually relevant search results, contributing to more effective and human-like information retrieval. Accordingly, the method of the present invention compiles contextually relevant chunks related to the query, making it possible for the generative model 14 to process large files. In one embodiment, the semantic similarity search 22 uses the domain knowledge base.

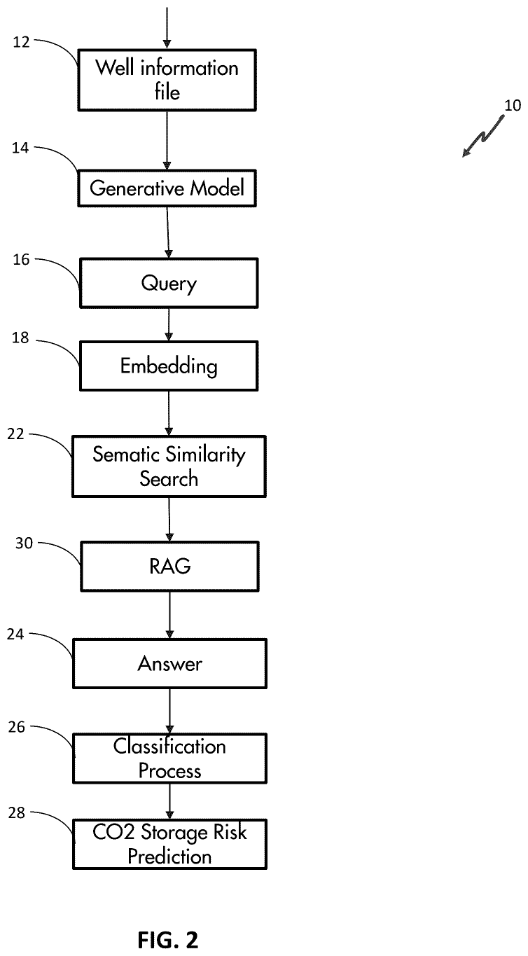

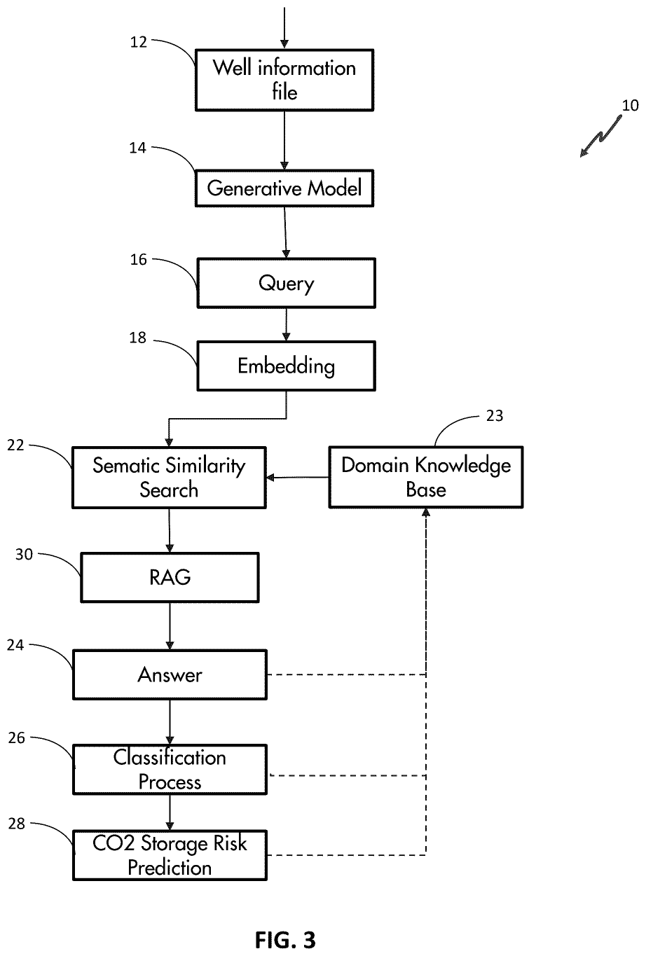

In preferred embodiments, illustrated in FIGS. 2 and 3, the generative model 14 includes Retrieval Augmentation Generation (RAG) 30 to integrate a retrieval mechanism with the generative model 14, allowing the generative model 14 to access more accurate and relevant information than it would have otherwise. In this way, when the well information file 12 has multiple pages, RAG 30 is able to assess the context of data on one page with data on another page in the well information file 12.

In the embodiment of FIG. 3, the domain knowledge base 23 is used in the semantic similarity search 22. The dashed arrows illustrate embodiments where the domain knowledge base 23 is provided with user feedback on one or more of the answer 24, the classification process 26, and the CO₂ storage risk assessment 28.

An answer 24 is generated by the generative model 14. The answer 24 is subjected to a classification process 26 to predict a well risk level for CO₂ containment.

The resulting risk assessment may be a relative risk level. Examples of relative risk levels include, without limitation, binary (e.g., yes/no) labels, high-medium-low labels, and/or a scale of risk levels having a finer level of detail. Depending on the criteria, different types of risk labels associated with certain well integrity criteria may be used within the same set of risk labels. For example, in certain embodiments, a yes/no risk level may be used for the presence or not of a cap rock seal, while a scale of risk level may be used as an indicator of casing integrity.

Examples of classification processes include, without limitation, artificial intelligence, machine learning, and deep learning. It will be understood by those skilled in the art that advances in classification processes continue rapidly. The method of the present invention is expected to be applicable to those advances even if under a different name. Accordingly, the method of the present invention is applicable to the further advances in classification processes, even if not expressly named herein.

The classification process is an unsupervised process, a supervised process, or a semi-supervised process. In one embodiment, a supervised process is made semi-supervised by the addition of an unsupervised technique.

The subsurface CO₂ risk assessment predicted from well data can be considered as an indicator of a vertical risk assessment, meaning that the prediction provides a localized assessment for the formation proximate the well. In a preferred embodiment, predictions for two or more wells are contextually assessed to compute a formation CO₂ storage risk assessment. The formation CO₂ risk assessment can be considered as an indicator of an areal risk assessment, meaning that the prediction provides an assessment for the formation proximate and between the wells. Contextual assessment may reveal, for example, migration pathways, a change in depth for a specific formation layer determined from well data may indicate a fracture that may or may not provide fluid communication. Such fluid communication may be an indicator of increased risk for use of the formation for CO₂ storage.

In a preferred embodiment, a subsurface CO₂ storage risk assessment for one well may be modified in view of a subsurface CO₂ storage risk assessment for another well in the same formation. For example, a subsurface CO₂ storage risk assessment for one well may show a layer in the subsurface formation that appears to be a low risk for CO₂ storage. However, a subsurface CO₂ storage risk assessment for another well may show a high risk for CO₂ storage in the same layer.

In another embodiment, the method may include the step of providing a recommendation for example, without limitation, to repair one or more wells, abandon a well, modifying a CO₂ injection scheme, and/or injecting CO₂ at a specified depth. This recommendation may be based on a subsurface CO₂ storage risk assessment for one or more wells, and/or a formation CO₂ storage risk assessment.

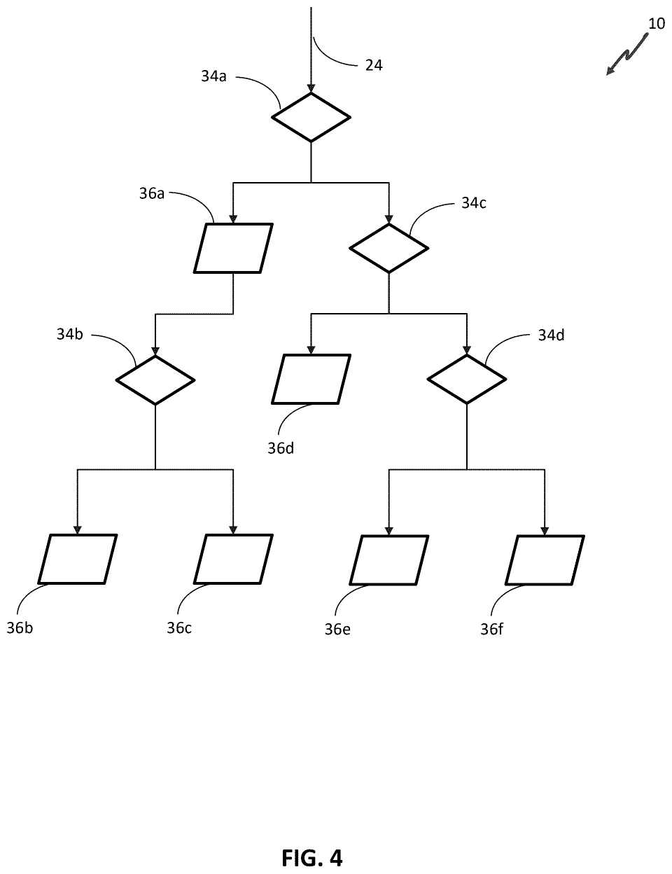

Referring now to FIG. 4 illustrating one embodiment of a set of well integrity rules for the present invention 10, the answer 24 is provided to a classification process wherein the answer 24 is queried with well integrity criteria 34. An initial and/or intermediate result of a well integrity criterion 34 may be a risk indicator 36 and/or a pass to another well integrity criterion 34. Ultimately, the classification process computes a prediction for a CO₂ storage risk assessment for a well for which the answer 24 was provided.

For example, the answer 24 may be interrogated for an initial well integrity criterion 34a, for example, related to a cap rock seal.

Following the left-hand side of FIG. 4, the initial well integrity criterion 34a may result in a high-risk indicator 36a. However, the classification process is trained to consider contextual relationships between well integrity criteria 24, such that the analysis continues on the left-hand side of FIG. 4. In response, a query for an intermediate well integrity criterion 34b, for example, related to isolation of the well from a groundwater zone, may result in a higher-risk indicator 36b or a medium-risk indicator 36c, depending on the response to the intermediate well integrity criterion 34b.

On the right-hand side of FIG. 4, the answer 24 passes the initial well integrity criterion 34a and is then interrogated with an intermediate well integrity criterion 34c, for example related to isolation of the well from a groundwater zone, may result in a higher-risk indicator 36d or a pass to another intermediate well integrity criterion 34d. Interrogation by the intermediate well integrity criterion 34d, for example related to isolation of the well from permeable zones in the formation, may result in a medium-risk indicator 36e or a low-risk indicator 36f, depending on the response to the intermediate well integrity criterion 34d.

The well integrity criteria 34 and resulting risk indicators 36 referred to in the discussion of FIG. 4 are provided as examples only. Other criteria may be used instead of or in combination with the above. Also, the order of the criteria 34 may be modified in accordance with the present invention 10. Further, the discussion above shows the intermediate well integrity criteria 34b and 34d are the same on the left-hand and right-hand sides of FIG. 4. However, the criteria 34b and 34d may not be the same.

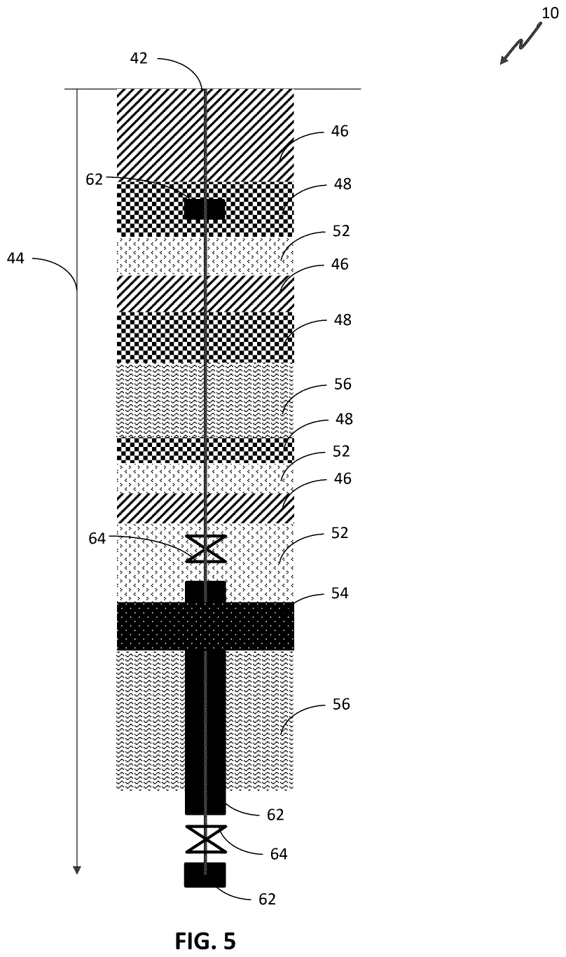

An example of a subsurface CO₂ storage risk assessment prepared by the method of the present invention for an existing well 42 based on legacy well data is illustrated in FIG. 5. The risk assessment provides a prediction for a low-risk CO₂ storage site is depicted as a function of depth 44.

FIG. 5 provides a simplified version of a formation stratigraphy and lithology for the formation proximate the well 42. Layers having forward slashes depict layers of unknown lithology 46. Layers providing a cap seal 48 are represented by checkered fill, while permeable layers 52 are shown with a divot fill. The permeable layers 52 were identified as medium-risk storage sites. A designated main seal layer 54 is depicted by light dots in a dark fill. FIG. 5 shows two permeable layers as having a low-risk CO₂ storage site 56, depicted with a wave fill.

The risk assessment shows the presence of a cement plug 62 shown with a solid fill and permanent bridge plugs 64.

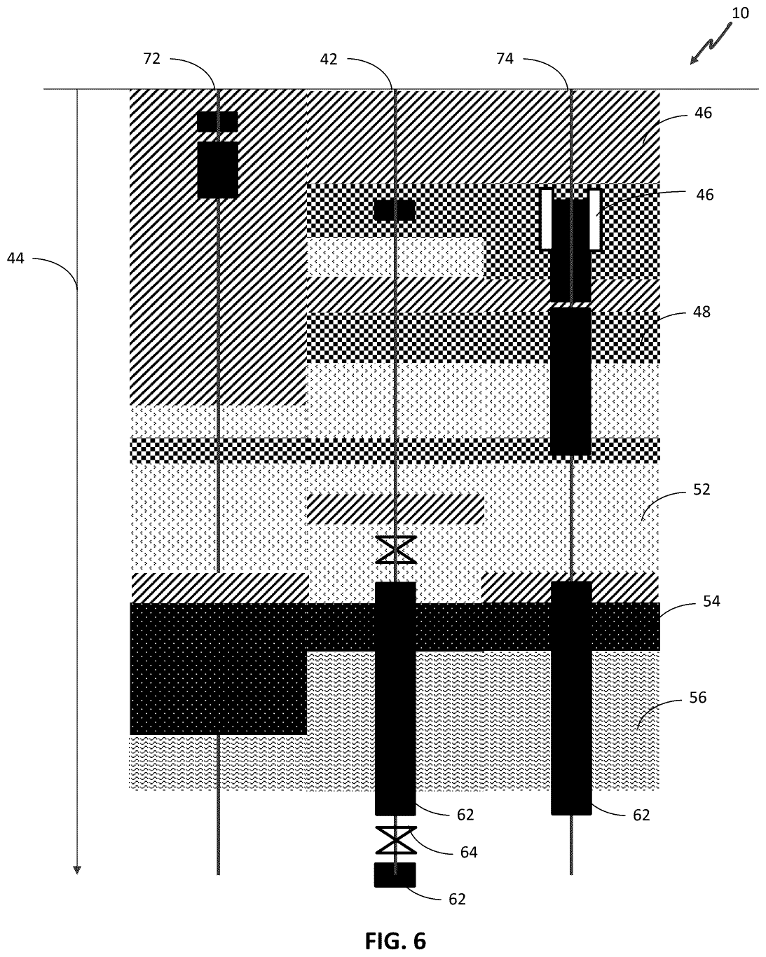

FIG. 6 illustrates an example of a formation CO₂ storage risk assessment prepared by a preferred embodiment of the method of the present invention for a formation having two additional wells 72, 74. The risk assessment for the well 42 from FIG. 5 is shown in the center of FIG. 6.

As for FIG. 5, FIG. 6 provides a simplified version of a formation lithology for the formation proximate the well 42. Layers having forward slashes depict layers of unknown lithology 46. Layers providing a cap seal 48 are represented by checkered fill, while permeable layers 52 are shown with a divot fill. The permeable layers 52 were identified as medium-risk storage sites. A designated main seal layer 54 is depicted by light dots in a dark fill. Another permeable layer was proposed as a low-risk CO₂ storage site 56 and is shown with a wave fill. FIG. 6 shows one embodiment of the invention, where a low risk assessment for the upper permeable layer 56 for well 42 in FIG. 5 was modified to a medium risk in view of the risk assessment of well 72.

The risk assessment shows the presence of a cement plug 62 shown with a solid fill and permanent bridge plugs 64. Well 74 also has casing cement 66 designated by open fill.

### EXAMPLES

The following non-limiting examples of an embodiment of the method of the present invention as claimed herein are provided for illustrative purposes only.

### Example 1

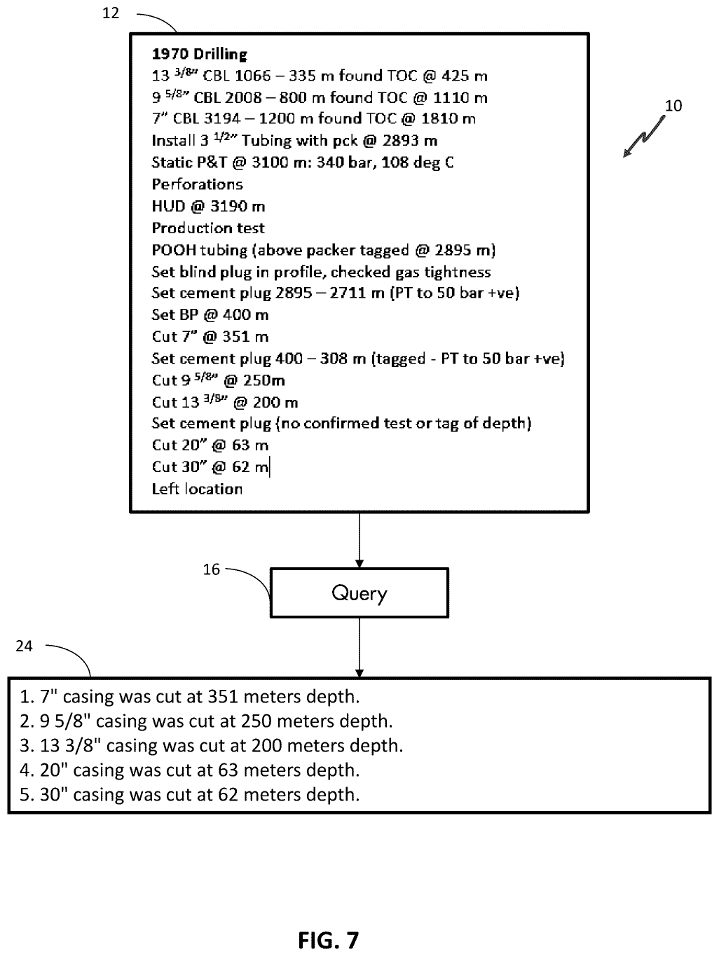

Example 1 compares the difference between a rule-based Natural-Language Processing (NLP) method to a generative model for extracting relevant information from a well information file 12. The well information file 12 was uploaded to a generative model in accordance with the present invention. The generative model was queried with “find the top and bottom depths of all the casing, including conductor, surface casing and production casing, each casing is longer than 18 feet, cut means casing top, and shoe means casing bottom, if there are multiple answers, please answer each pair of top and bottom in a JSON format”. The answer 24, illustrated in FIG. 7, indicates five cutting depths for five different casings.

By way of comparison, the well information file 12 was uploaded to an NLP model based on predefined rules. The result was “No Casing Found”.

### Example 2

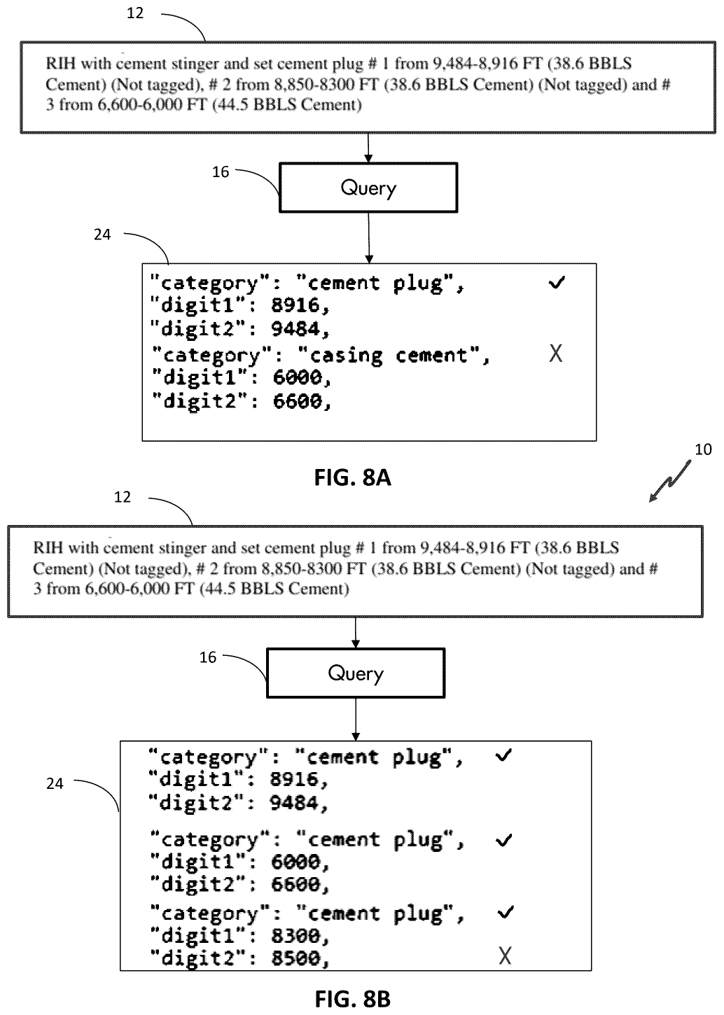

Example 2 illustrates semantic understanding using a generative model compared to a rule-based NLP method. In FIG. 8A, a well information file 12 was queried by an NLP method. The rules used for rule-based NLP were:
1. If the number follows the keyword cement plug and is within 10 words distance from keyword;
2. The number ends with units m or ft;
3. The number is within reasonable value range: 10-90000;
4. If multiple pairs of numbers are found with in qualified sentence, pick the shorter distance pair of numbers as the final answer.

The resulting answer 24 indicates that an error (indicated by “X”) was made in identifying a “casing cement” instead of a “casing plug” in one instance. As well, the NLP method failed to extract the cement plug at “8850-8300 FT.” The rule-based NLP system missed the numbers (8850-8300) because they were more than 10 words away from the keyword “cement plug,” violating the rule mentioned above that the numbers must be within a 10-word distance. Additionally, since the system is designed to select the first number pair within the distance, as the second numbers, despite being relevant, they were ignored due to their position and the rule's constraints.

FIG. 8B illustrates the answer produced by uploading and querying the same well information file 12 to a generative AI model. The generative model was queried with “find all the top and bottom depths of all the cement plugs, length should be longer than 10 meters, there should be less than 8 cement plugs, please answer each pair of top and bottom in a JSON format.” The resulting answer 24 properly identified three cement plugs. One error occurred for the third cement plug, where the “digit2” answer was 8500, instead of 8850 per the well information file 12.

### Example 3

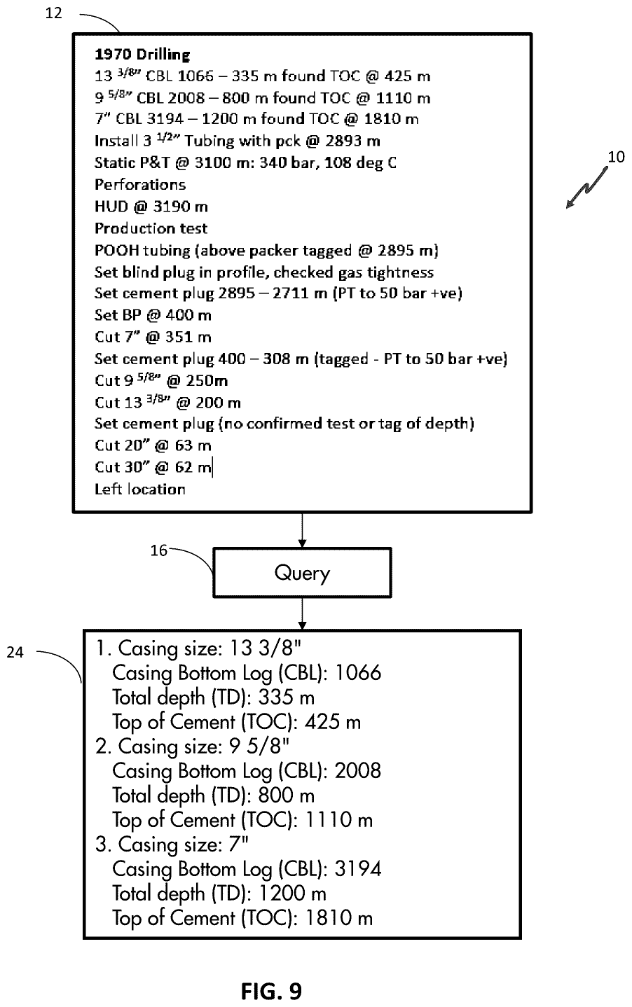

Example 3 compares the difference in flexibility between a rule-based Natural-Language Processing (NLP) method to a generative model for extracting relevant information from a well information file 12. The well information file 12 was uploaded to a generative model in accordance with the present invention. The generative model was queried with “find the casing cement, if there are multiple answers, please answer each pair of top and bottom in a JSON format”. The answer 24, illustrated in FIG. 9, indicates casing bottom log, total depth, and top of cement for three casing sizes. This illustrates the flexibility in the method of the present invention to understand context and patterns without being limited to strict predefined rules, allowing the model to adapt to a wider variety of text structures. For example, in this case, the user didn't define a pattern like “TOC@followed by numbers” to extract casing cement, but the model can extract 425 as top of casing cement.

By way of comparison, the well information file 12 was uploaded to a NLP model based on predefined rules. The result was “No Casing Cement Found.”

### Example 4

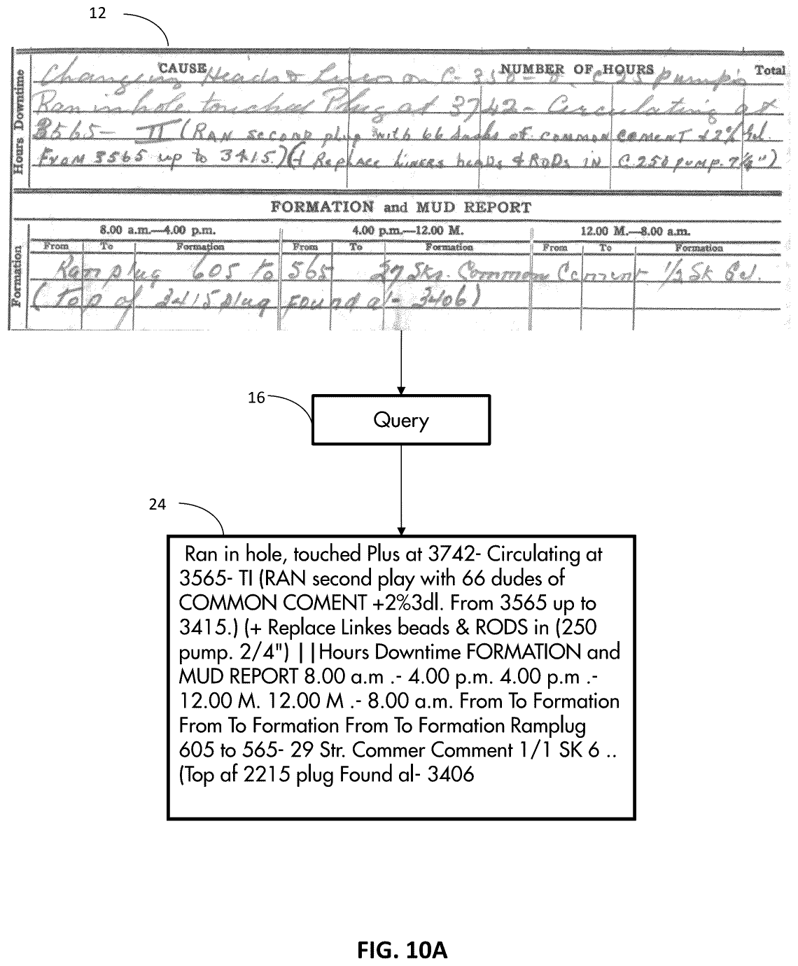

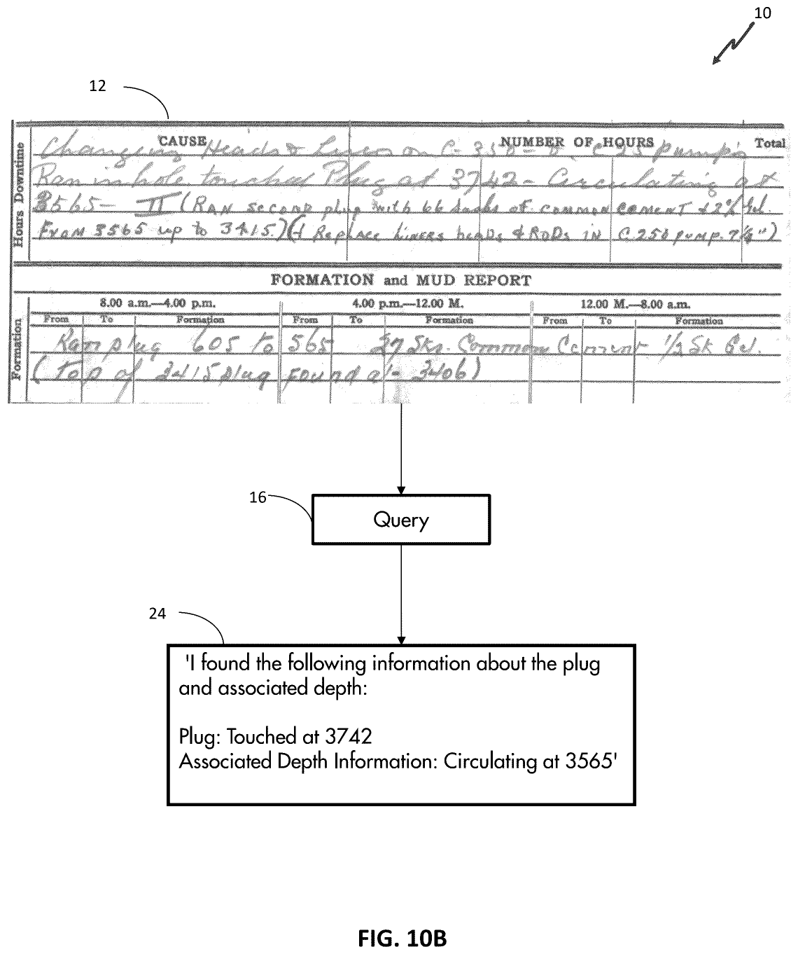

Example 4 compares the difference in ambiguity between a rule-based Natural-Language Processing (NLP) method to a generative model for extracting relevant information from a well information file 12. In the field of well completion and abandonment, well information files may be provided in handwritten form, such as illustrated in FIGS. 10A and 10B.

For comparative purposes, the well information file 12 was uploaded to a NLP model based on predefined rules. The answer 26 is shown in FIG. 10A. Because there are many OCR errors, the text is ambiguous, so the rule-based-NLP can't extract any useful information.

The well information file 12 was uploaded to a generative model in accordance with the present invention. The generative model was queried with “find the cement plug, if there are multiple answers, please answer each pair of top and bottom in a JSON format”. The answer 24, illustrated in FIG. 10B, indicates the location of a cement plug. Despite the ambiguity provided by the handwritten word “Plug,” the generative model understood the context and was able to recognize that the word should be “Plug,” rather than “Plus” as understood by the NLP method.

### Example 5

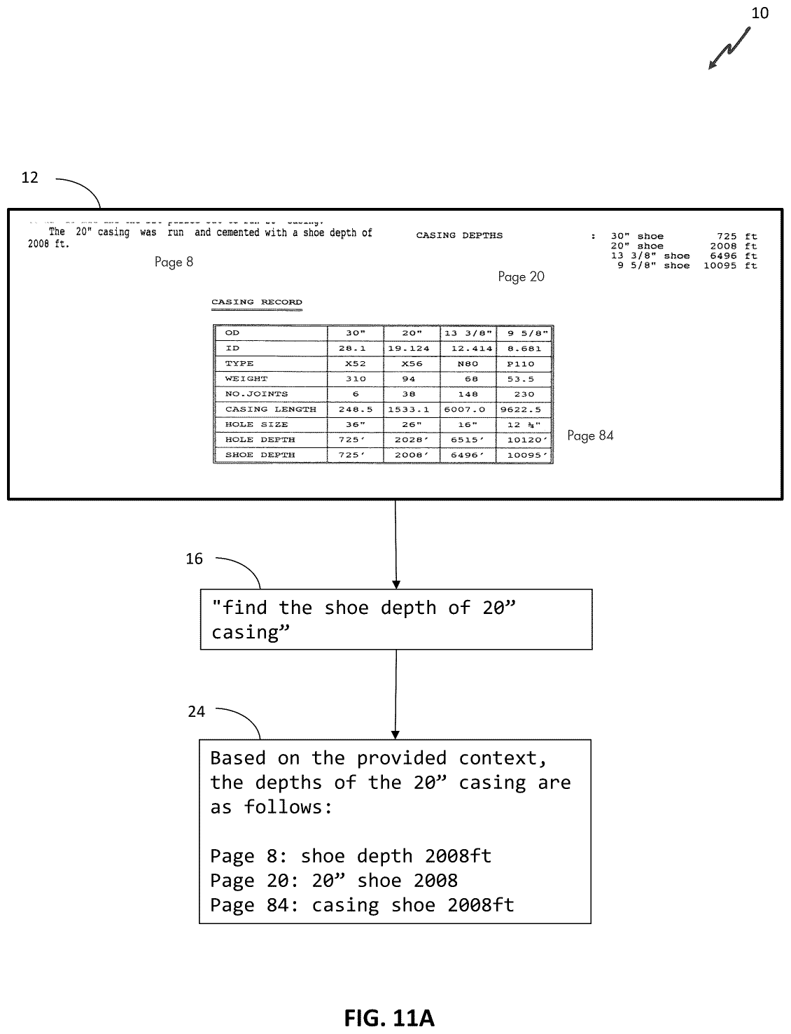

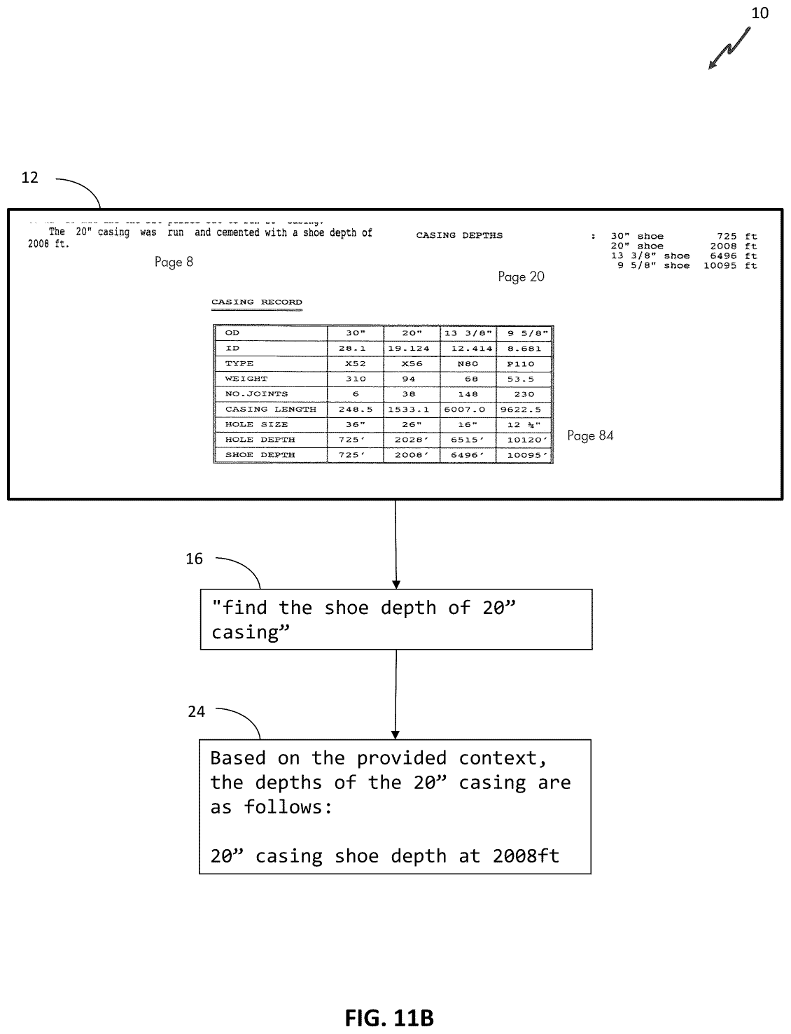

Example 5 compares the difference in answers provided by generative models, with and without RAG. FIGS. 11A, 11B show a well information file 12 having multiple pages. The generative model is queried 16 with “find the shoe depth of 20” casing.” FIG. 11A shows the answer 24 produced by the generative model, which provides answers from pages 8, 20 and 84. When feeding the model one page at a time, the model will treat each page as an individual file. One issue is the potential generation of duplicated answers from each page, necessitating post-processing to rectify.

FIG. 11B shows the answer 24 produced by the generative model with RAG 30. RAG 30 filters out non-relevant content, thereby enabling the feeding of all pertinent content to the generative model simultaneously. This allows the model to grasp context more effectively, thereby assisting in eliminating redundant answers.

### Example 6

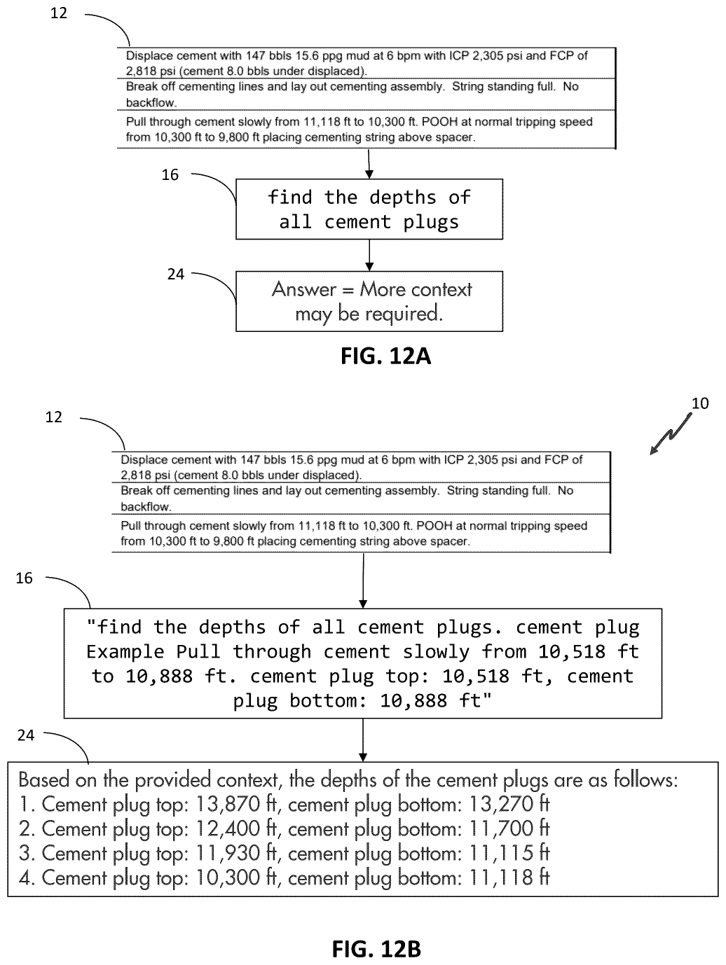

Example 6 compares the difference in answers provided by generative models, with and without one-shot learning. With the query 16 “find the depths of all cement plugs”, i.e., without few-shot learning, the generative model was unable to answer the question, asking instead for more context, as shown in FIG. 12A.

FIG. 12B shows one-shot learning applied to the query 16. Here the query is phrased “find the depths of all cement plugs. cement plug Example Pull through cement slowly from 10,518 ft to 10,888 ft. cement plug top: 10,518 ft, cement plug bottom: 10,888 ft.” The generative model was able to generate an answer 24 providing the depth of the cement plug top and cement plug bottom for four instances in the well information file 12.

While preferred embodiments of the present invention have been described, it should be understood that various changes, adaptations, and modifications can be made therein within the scope of the invention(s) as claimed below.

What is claimed is:

1. A method for predicting a CO₂ storage risk assessment, comprising the steps of:
a) providing a generative model;
b) determining a set of well integrity rules;
c) uploading a well information file for a well located in a subsurface formation to the generative model;
d) querying the well information file to extract information relevant to the set of well integrity rules from the well information file;
e) embedding to convert the query and the extracted information into numerical vectors;
f) conducting a semantic similarity search to find and rank text using the numerical vectors;
g) providing an answer to the query generated by the generative model to a classification process based on the set of well integrity rules; and
h) computing a prediction for a subsurface CO₂ storage risk assessment for the well from the answer generated in step (g).

2. The method of claim 1, wherein the querying step is performed by an example learning technique selected from few-shot learning and one-shot learning.

3. The method of claim 1, wherein step of conducting a semantic similarity search further comprises using a domain knowledge base trained by an example learning technique selected from few-shot learning and one-shot learning.

4. The method of claim 1, wherein the generative model is selected from a large-language model, a large vision model, and a large vision-language model.

5. The method of claim 1, further comprising a Retrieval Augmentation Generation step.

6. The method of claim 1, wherein the set of well integrity rules comprises criteria selected from the group consisting of presence of a cap rock seal, well casing integrity, open or closed perforations in the wells, proximity to groundwater zone, isolation of groundwater zones using plugs or otherwise, fluid communication with a permeable zone, industry standards, industry guidelines, governmental regulations, and combinations thereof.

7. The method of claim 1, further comprising the step of providing a recommendation for repairs to the first well, abandoning the well, modifying an injection scheme, injecting CO₂ at a specified depth, and combinations thereof.

8. The method of claim 1, wherein the classification process is selected from a supervised classification process, an unsupervised classification process, and a semi-supervised classification process.
